(19) United States
(12) Patent Application Publication
(10) Pub. No.: US 2026/0237446 A1
(43) Pub. Date: Aug. 13, 2026

(54) READING METHOD, MEMORY STORAGE DEVICE AND MEMORY CONTROL CIRCUIT UNIT

(71) Applicant: PHISON ELECTRONICS CORP., Miaoli (TW)

(72) Inventors: Yu-Heng Liu, Hsinchu County (TW); Yu-Siang Yang, New Taipei City (TW); Chia-Cheng Hsu, New Taipei City (TW)

(73) Assignee: PHISON ELECTRONICS CORP., Miaoli (TW)

(21) Appl. No.: 19/060,786

(22) Filed: Feb. 24, 2025

(30) Foreign Application Priority Data
Feb. 11, 2025 (TW) 114104953

(51) Int. Cl. G11C 16/34; G11C 16/04; G11C 16/26

(52) U.S. Cl. CPC G11C 16/3495; G11C 16/0483; G11C 16/26

(57) ABSTRACT

The disclosure provides a reading method, a memory storage device, and a memory control circuit unit. The reading method includes: applying a read pass voltage to memory cells of a first physical unit; calculating an open bit number of the memory cells connected to a bit line and cut off when the read pass voltage is applied for each bit line, wherein the open bit number corresponding to a first bit line is different from the open bit number corresponding to a second bit line; setting different read voltages; and applying a first read voltage to the memory cells connected to the first bit line in a second physical unit and applying a second read voltage to the memory cells connected to the second bit line in the second physical unit when reading the second physical unit, thereby obtaining data bits of the second physical unit.

### CROSS-REFERENCE TO RELATED APPLICATION

This application claims the priority benefit of Taiwan application serial no. 114104953, filed on Feb. 11, 2025. The entirety of the above-mentioned patent application is hereby incorporated by reference herein and made a part of this specification.

### BACKGROUND OF THE INVENTION

### Field of the Invention

The disclosure relates to a reading method of a rewritable non-volatile memory module that may solve the wear issue of the rewritable non-volatile memory module.

### Description of Related Art

Portable electronic devices such as mobile phones and notebook computers have grown rapidly in the past few years, which has led to a rapid increase in consumer demand for storage media. Since a rewritable non-volatile memory module (such as a flash memory) has characteristics such as data non-volatility, power-saving, small size, and lack of mechanical structures, the rewritable non-volatile memory module is very suitable to be built into the various portable electronic devices provided above.

Moreover, with the development of artificial intelligence techniques, the access frequency (especially data writing frequency) of processing circuits such as central processing unit (CPU), graphics processing unit (GPU), video processing unit (VPU), neural network processing unit (NPU), and tensor processing unit (TPU) to the rewritable non-volatile memory module is also significantly increased, resulting in a significant increase in the wear rate of the rewritable non-volatile memory module. Therefore, how to cope with the accelerated wear of the rewritable non-volatile memory module caused by a large number of accesses to the rewritable non-volatile memory module during the calculation process of the artificial intelligence model is one of the topics that those skilled in the art have devoted themselves to studying.

### SUMMARY OF THE INVENTION

The disclosure provides a reading method, a memory storage device, and a memory control circuit unit that may solve the issue of threshold voltage rising after the physical unit wears out.

The disclosure provides a reading method for a rewritable non-volatile memory module. The rewritable non-volatile memory module includes a plurality of physical units and a plurality of bit lines. The reading method includes: applying a read pass voltage to a plurality of first memory cells of a first physical unit to determine whether the first memory cells are turned on or cut off, wherein each of the first memory cells is connected to a bit line; calculating an open bit number of the first memory cells connected to the bit line and cut off when the read pass voltage is applied for each of the bit lines, wherein the open bit number corresponding to a first bit line is different from the open bit number corresponding to a second bit line; setting a plurality of read voltages, including a first read voltage and a second read voltage, wherein the first read voltage is different from the second read voltage; applying the first read voltage to a second memory cell connected to the first bit line in a second physical unit, and applying the second read voltage to a second memory cell connected to the second bit line in the second physical unit when reading the second physical unit, thereby obtaining a plurality of first data bits of the second physical unit.

In an embodiment of the disclosure, the open bit number corresponding to the first bit line is greater than the open bit number corresponding to the second bit line, and the first read voltage is greater than the second read voltage.

In an embodiment of the disclosure, the step of setting the read voltages includes: setting the read voltages according to the open bit number corresponding to the bit line, wherein the open bit number and the read voltages are positively correlated.

In an embodiment of the disclosure, the reading method further includes: determining whether the first data bit passes an error checking procedure; applying the read pass voltage to a plurality of third memory cells of a third physical unit to determine whether the third memory cells are turned on or cut off in a case that the first data bit does not pass the error checking procedure, wherein each of the third memory cells is connected to the bit line; calculating an open bit distribution of the first memory cells and the third memory cells connected to the bit line and cut off when the read pass voltage is applied for each of the bit lines, wherein the open bit distribution corresponding to the first bit line is different from the open bit distribution corresponding to the second bit line; and applying a third read voltage to the second memory cell connected to the first bit line in the second physical unit, and applying a fourth read voltage in the read voltage to the second memory cell connected to the second bit line in the second physical unit, thereby reading a plurality of second data bits of the second physical unit.

In an embodiment of the disclosure, a number of the first memory cells and the third memory cells connected to the first bit line and cut off when the read pass voltage is applied is greater than a number of the first memory cells and the third memory cells connected to the second bit line and cut off when the read pass voltage is applied, and the third read voltage is greater than the fourth read voltage.

In an embodiment of the disclosure, the reading method further includes: storing the open bit distribution corresponding to the bit line in a buffer memory; and reading the open bit distribution from the buffer memory to determine that the first bit line corresponds to the first read voltage and the second bit line corresponds to the second read voltage when reading the second physical unit.

In an embodiment of the disclosure, the second physical unit is different from at least one of the first physical units.

From another perspective, an embodiment of the invention provides a memory storage device, including: a connection interface unit configured to be coupled to a host system; a rewritable non-volatile memory module including a plurality of physical units and a plurality of bit lines; and a memory control circuit unit coupled to the connection interface unit and the rewritable non-volatile memory module. The memory control circuit unit is configured to perform a plurality of steps: applying a read pass voltage to a plurality of first memory cells of a first physical unit to determine whether the first memory cells are turned on or cut off, wherein each of the first memory cells is connected to a bit line; calculating an open bit number of the first memory cells connected to the bit line and cut off when the read pass voltage is applied for each of the bit lines, wherein the open bit number corresponding to a first bit line is different from the open bit number corresponding to a second bit line; setting a plurality of read voltages, including a first read voltage and a second read voltage, wherein the first read voltage is different from the second read voltage; applying the first read voltage to a second memory cell connected to the first bit line in a second physical unit, and applying the second read voltage to a second memory cell connected to the second bit line in the second physical unit when reading the second physical unit, thereby obtaining a plurality of first data bits of the second physical unit.

From another perspective, an embodiment of the invention provides a memory control circuit unit configured to control a rewritable non-volatile memory module. The memory control circuit unit includes: a host interface configured to be coupled to a host system; a memory interface configured to be coupled to a rewritable non-volatile memory module; and a memory management circuit coupled to the host interface and the memory interface. The memory management circuit is configured to perform a plurality of steps: applying a read pass voltage to a plurality of first memory cells of a first physical unit to determine whether the first memory cells are turned on or cut off, wherein each of the first memory cells is connected to a bit line; calculating an open bit number of the first memory cells connected to the bit line and cut off when the read pass voltage is applied for each of the bit lines, wherein the open bit number corresponding to a first bit line is different from the open bit number corresponding to a second bit line; setting a plurality of read voltages, including a first read voltage and a second read voltage, wherein the first read voltage is different from the second read voltage; applying the first read voltage to a second memory cell connected to the first bit line in a second physical unit, and applying the second read voltage to a second memory cell connected to the second bit line in the second physical unit when reading the second physical unit, thereby obtaining a plurality of first data bits of the second physical unit.

In order to make the aforementioned features and advantages of the disclosure more comprehensible, embodiments accompanied with figures are described in detail below.

### BRIEF DESCRIPTION OF THE DRAWINGS

FIG. 1 is a schematic diagram of a host system, a memory storage device, and an input/output (I/O) device shown according to an exemplary embodiment of the invention.

FIG. 2 is a schematic diagram of a host system, a memory storage device, and an I/O device shown according to an exemplary embodiment of the invention.

FIG. 3 is a schematic of a host system and a memory storage device shown according to an exemplary embodiment of the invention.

FIG. 4A is a schematic diagram of a memory storage device shown according to an exemplary embodiment of the invention.

FIG. 4B is a schematic diagram of a memory cell array shown according to an exemplary embodiment of the invention.

FIG. 5 is a schematic diagram of a memory control circuit unit shown according to an exemplary embodiment of the invention.

FIG. 6 is a schematic diagram of the management of a rewritable non-volatile memory module shown according to an exemplary embodiment of the invention.

FIG. 7 is a schematic diagram illustrating reading a read pass voltage according to an embodiment.

FIG. 8 is a flowchart illustrating a reading method according to an embodiment.

FIG. 9 is a schematic diagram illustrating applying a read voltage according to an embodiment.

FIG. 10 is a schematic diagram illustrating applying a read voltage according to an embodiment.

FIG. 11 is a schematic diagram illustrating applying a read voltage according to an embodiment.

FIG. 12 is a flowchart illustrating a reading method according to another embodiment.

FIG. 13 is a schematic diagram illustrating selecting a third physical unit according to an embodiment.

### DESCRIPTION OF THE EMBODIMENTS

A portion of the embodiments of the disclosure is described in detail hereinafter with reference to figures. In the following, the same reference numerals in different figures should be considered to represent the same or similar elements. These embodiments are only a portion of the invention and do not disclose all possible implementations of the invention. Rather, the embodiments are merely examples of systems and methods within the scope of the invention.

The terms “first”, “second”, etc. used in the specification do not specifically refer to the order or sequence, but are only used to distinguish elements or operations described with the same technical terms.

In general, a memory storage device (also called a memory storage system) includes a rewritable non-volatile memory module and a controller (also called a control circuit). The memory storage device may be used with a host system, such that the host system may write data into the memory storage device or read data from the memory storage device.

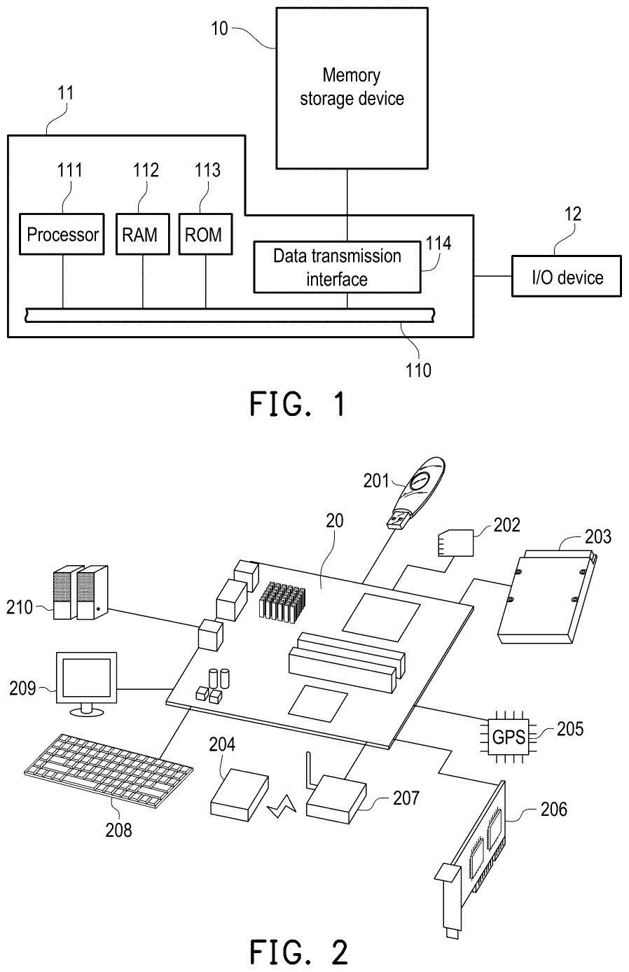

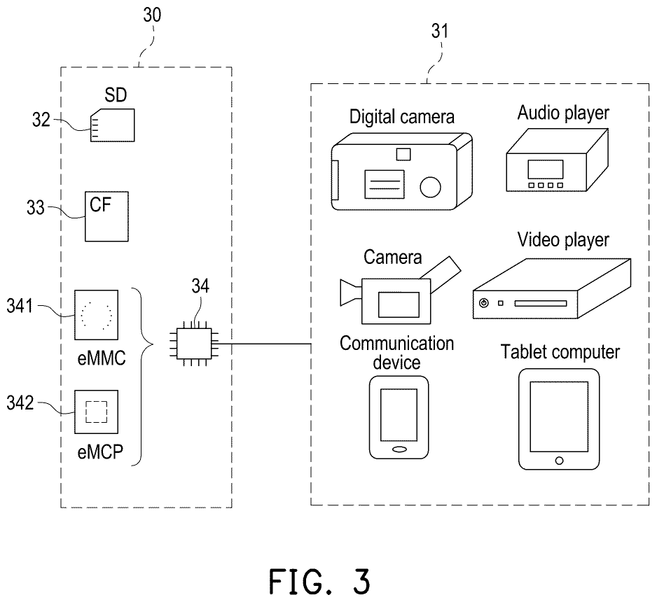

FIG. 1 is a schematic diagram of a host system, a memory storage device, and an input/output (I/O) device shown according to an exemplary embodiment of the invention. FIG. 2 is a schematic diagram of a host system, a memory storage device, and an I/O device shown according to an exemplary embodiment of the invention.

Referring to FIG. 1 and FIG. 2, a host system 11 may include a processor 111, a random-access memory (RAM) 112, a read-only memory (ROM) 113, and a data transmission interface 114. The processor 111, the RAM 112, the ROM 113, and the data transmission interface 114 may be coupled to a system bus 110.

In an exemplary embodiment, the host system 11 may be coupled to the memory storage device 10 via the data transmission interface 114. For example, the host system 11 may store data in the memory storage device 10 or read data from the memory storage device 10 via the data transmission interface 114. Moreover, the host system 11 may be coupled to the I/O device 12 via the system bus 110. For example, the host system 11 may send an output signal to the I/O device 12 or receive an input signal from the I/O device 12 via the system bus 110.

In an exemplary embodiment, the processor 111, the RAM 112, the ROM 113, and the data transmission interface 114 may be disposed on a motherboard 20 of the host system 11. The number of the data transmission interface 114 may be one or a plurality.

The motherboard 20 may be coupled to the memory storage device 10 in a wired or wireless method via the data transmission interface 114.

In an exemplary embodiment, the memory storage device 10 may be, for example, a flash drive 201, a memory card 202, a solid-state drive (SSD) 203, or a wireless memory storage device 204. The wireless memory storage device 204 may be, for example, a memory storage device based on various wireless communication techniques such as a Near-Field Communication (NFC) memory storage device, a WiFi memory storage device, a Bluetooth memory storage device, or a low-power Bluetooth memory storage device (e.g., iBeacon). Moreover, the motherboard 20 may also be coupled to various I/O devices such as a global positioning system (GPS) module 205, a network interface card 206, a wireless transfer device 207, a keyboard 208, a screen 209, or a speaker 210 via the system bus 110. For example, in an exemplary embodiment, the motherboard 20 may access the wireless memory storage device 204 via the wireless transfer device 207.

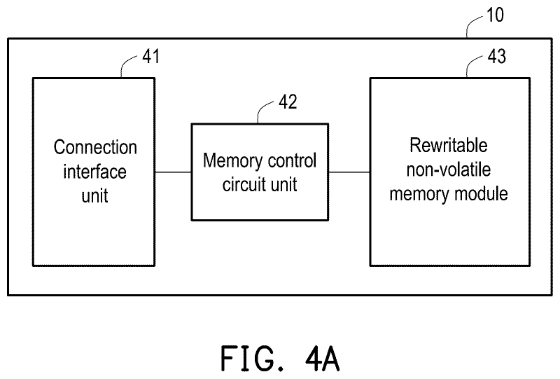

In an exemplary embodiment, the host system 11 is a computer system. In an exemplary embodiment, the host system 11 may be any system that may substantially store data with the memory storage device. In an exemplary embodiment, the memory storage device 10 and the host system 11 may include a memory storage device 30 and a host system 31 of FIG. 3, respectively.

FIG. 3 is a schematic of a host system and a memory storage device shown according to an exemplary embodiment of the invention. Referring to FIG. 3, the memory storage device 30 may be used in conjunction with the host system 31 to store data. For example, the host system 31 may be a digital camera, a camera, a communication device, an audio player, a video player, or a tablet computer. For example, the memory storage device 30 may be various non-volatile memory storage devices such as a Secure Digital (SD) card 32, a Compact Flash (CF) card 33, or an embedded storage device 34 used by the host system 31. The embedded storage device 34 includes various types of embedded storage devices for which a memory module is directly coupled on the substrate of the host system, such as an embedded multimedia card (eMMC) 341 and/or an embedded multi-chip package (eMCP) storage device 342.

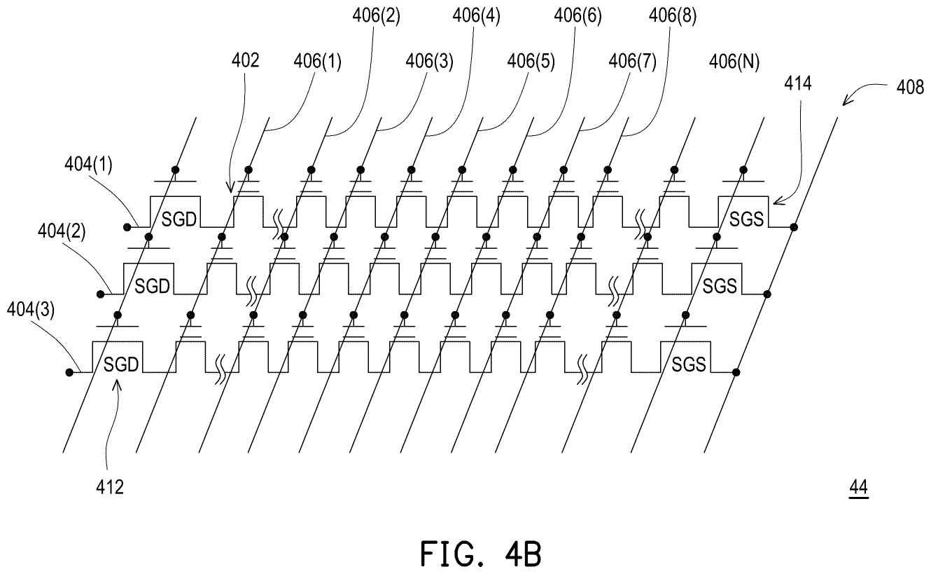

FIG. 4A is a schematic diagram of a memory storage device shown according to an exemplary embodiment of the invention. Referring to FIG. 4A, the memory storage device 10 includes a connection interface unit 41, a memory control circuit unit 42, and a rewritable non-volatile memory module 43.

The connection interface unit 41 is configured to be coupled to the host system 11. The memory storage device 10 may be communicated with the host system 11 via the connection interface unit 41. In an exemplary embodiment, the connection interface unit 41 is compatible with the Peripheral Component Interconnect Express (PCI Express) standard. In an exemplary embodiment, the connection interface unit 41 may also conform to Serial Advanced Technology Attachment (SATA) standard, Parallel Advanced Technology Attachment (PATA) standard, Institute of Electrical and Electronic Engineers (IEEE) 1394 standard, Universal Serial Bus (USB) standard, SD interface standard, Ultra High Speed-I (UHS-I) interface standard, Ultra High Speed-II (UHS-II) interface standard, Memory Stick (MS) interface standard, MCP interface standard, MMC interface standard, eMMC interface standard, Universal Flash Storage (UFS) interface standard, eMCP interface standard, CF interface standard, Integrated Device Electronics (IDE) standard, or other suitable standards. The connection interface unit 41 may be sealed in a chip with the memory control circuit unit 42. Alternatively, the connection interface unit 41 is disposed outside of a chip containing the memory control circuit unit 42.

The memory control circuit unit 42 is coupled to the connection interface unit 41 and the rewritable non-volatile memory module 43. The memory control circuit unit 42 is configured to execute a plurality of logic gates or control commands implemented in hardware or firmware and to perform operations such as writing, reading, and erasing data in the rewritable non-volatile memory module 43 according to the commands of the host system 11.

The rewritable non-volatile memory module 43 is configured to store data written by the host system 11. The rewritable non-volatile memory module 43 may include a single-level cell (SLC) NAND-type flash memory module (that is, a flash memory module that may store 1 bit in one memory cell), a multi-level cell (MLC) NAND-type flash memory module (that is, a flash memory module that may store 2 bits in one memory cell), a triple-level cell (TLC) NAND-type flash memory module (that is, a flash memory module that may store 3 bits in one memory cell), a quad-level cell (QLC) NAND-type flash memory module (that is, a flash memory module that may store 4 bits in one memory cell), other flash memory modules, or other memory modules having the same characteristics.

Each of the memory cells in the rewritable non-volatile memory module 43 stores one or a plurality of bits via the change in voltage (also called threshold voltage hereinafter). Specifically, there is a charge-trapping layer between the control gate and the channel of each memory cell. By applying a write voltage to the control gate, the amount of electrons of the charge-trapping layer may be changed, thereby changing the threshold voltage of the memory cell. This operation of changing the threshold voltage of a memory cell is also called “writing data into a memory cell” or “programming a memory cell”. As the threshold voltage is changed, each of the memory cells in the rewritable non-volatile memory module 43 has a plurality of storage statuses. Which storage status one memory cell belongs to may be determined via the application of a read voltage, so as to obtain one or a plurality of bits stored by the memory cell.

FIG. 4B is a schematic diagram of a memory cell array shown according to an exemplary embodiment of the invention. Referring to FIG. 4B, the memory cell array 44 includes a plurality of memory cells 402 configured to store data, a plurality of select gate drain (SGD) transistors 412 and a plurality of select gate source (SGS) transistors 414, a plurality of bit lines 404(1) to 404(3) connecting the memory cells 402, a plurality of word lines 406(1) to 406(N), and a common source line 408, wherein N is a positive integer. In particular, the memory cells 402 are disposed in an array at the intersections of the bit lines 404(1) to 404(3) and the word lines 406(1) to 406(N), as shown in FIG. 4B. FIG. 4B is only an example, and the invention does not limit the number of word lines and bit lines in one memory cell array 44. In addition, the rewritable non-volatile memory module 43 may include a plurality of memory cell arrays 44. The memory cell arrays 44 may be stacked horizontally and/or vertically.

In an exemplary embodiment, the memory cells of the rewritable non-volatile memory module 43 may form a plurality of physical programming units, and the physical programming units may form a plurality of physical erasing units. Specifically, the memory cells on the same word line may form one or a plurality of physical programming units. In a case that each memory cell may store 2 or more bits, the physical programming units on the same word line may at least be classified into lower physical programming units and upper physical programming units. For example, the least significant bit (LSB) of a memory cell belongs to the lower physical programming units, and the most significant bit (MSB) of a memory cell belongs to the upper physical programming units. Generally, in an MLC NAND-type flash memory, the write speed of the lower physical programming units is greater than the write speed of the upper physical programming units, and/or the reliability of the lower physical programming units is greater than the reliability of the upper physical programming units.

In an exemplary embodiment, the physical programming unit is the smallest unit of programming. That is, the physical programming unit is the smallest unit for writing data. For example, the physical programming unit may be a physical page or a physical sector. In a case that the physical programming unit is a physical page, the physical programming units may include a data bit area and a redundancy bit area. The data bit area contains a plurality of physical pages configured to store user data, and the redundancy bit area is configured to store system data (for example, management data such as an error checking code (ECC)). In an exemplary embodiment, the data bit area includes 32 physical sectors, and the size of one physical sector is 512 bytes (B). However, in other exemplary embodiments, the data bit area may also contain 8, 16, or a greater or lesser number of physical sectors, and the size of each of the physical sectors may also be greater or less. Moreover, the physical erasing unit is the smallest unit of erasing. That is, each physical erasing unit contains a minimum number of memory cells erased together. For example, the physical erasing unit is a physical block.

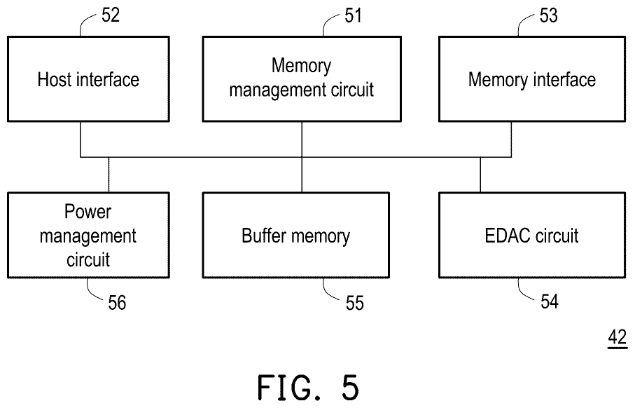

FIG. 5 is a schematic diagram of a memory control circuit unit shown according to an exemplary embodiment of the invention. Referring to FIG. 5, the memory control circuit unit 42 includes a memory management circuit 51, a host interface 52, and a memory interface 53.

The memory management circuit 51 is configured to control the overall operation of the memory control circuit unit 42. Specifically, the memory management circuit 51 has a plurality of control commands. During the operation of the memory storage device 10, the control commands are executed to perform operations such as writing, reading, and erasing data. In the following, descriptions relating to the operations of the memory management circuit 51 are equivalent to the descriptions of the operations of the memory control circuit unit 42 and the memory storage device 10.

In an exemplary embodiment, the control commands of the memory management circuit 51 are implemented in a firmware form. For example, the memory management circuit 51 has a microprocessor unit (not shown) and a read-only memory (not shown), and the control commands are burned into the ROM. During the operation of the memory storage device 10, the control commands are executed by the microprocessor unit to perform operations such as writing, reading, and erasing data.

In an exemplary embodiment, the control commands of the memory management circuit 51 may also be stored in a specific area of the rewritable non-volatile memory module 43 (e.g., a system area in the memory module dedicated to storing system data) in the form of program code. Moreover, the memory management circuit 51 has a microprocessor unit (not shown), a ROM (not shown), and a RAM (not shown). In particular, the ROM has a boot code, and when the memory control circuit unit 42 is enabled, the microprocessor unit first executes the boot code to load the control commands stored in the rewritable non-volatile memory module 43 into the RAM of the memory management circuit 51. Next, the microprocessor unit executes the control commands to perform operations such as writing, reading, and erasing data.

In an exemplary embodiment, the control commands of the memory management circuit 51 may also be implemented in a hardware form. For example, the memory management circuit 51 includes a microcontroller, a memory cell management circuit, a memory write circuit, a memory read circuit, a memory erase circuit, and a data processing circuit. The memory cell management circuit, the memory write circuit, the memory read circuit, the memory erase circuit, and the data processing circuit are coupled to the microcontroller. The memory cell management circuit is configured to manage the memory cells or the memory cell groups of the rewritable non-volatile memory module 43. The memory write circuit is configured to issue a write command sequence to the rewritable non-volatile memory module 43 to write data into the rewritable non-volatile memory module 43. The memory read circuit is configured to issue a read command sequence to the rewritable non-volatile memory module 43 to read data from the rewritable non-volatile memory module 43. The memory erase circuit is configured to issue an erase command sequence to the rewritable non-volatile memory module 43 to erase data from the rewritable non-volatile memory module 43. The data processing circuit is configured to process data to be written into the rewritable non-volatile memory module 43 and data to be read from the rewritable non-volatile memory module 43. The write command sequence, the read command sequence, and the erase command sequence may independently include one or a plurality of program codes or command codes and be configured to instruct the rewritable non-volatile memory module 43 to perform corresponding operations such as writing, reading, and erasing. In an exemplary embodiment, the memory management circuit 51 may also issue other types of command sequences to the rewritable non-volatile memory module 43 to instruct the performance of corresponding operations.

The host interface 52 is coupled to the memory management circuit 51. The memory management circuit 51 may be communicated with the host system 11 via the host interface 52. The host interface 52 may be configured to obtain and identify commands and data from the host system 11. For example, the commands and the data of the host system 11 may be sent to the memory management circuit 51 via the host interface 52. In addition, the memory management circuit 51 may send the data to the host system 11 via the host interface 52. In the present exemplary embodiment, the host interface 52 is compatible with the PCI Express standard. However, it should be understood that the invention is not limited thereto, and the host interface 52 may also be compatible with SATA standard, PATA standard, IEEE 1394 standard, USB standard, SD standard, UHS-I standard, UHS-II standard, MS standard, MMC standard, eMMC standard, UFS standard, CF standard, IDE standard, or other suitable standards for data transmission.

The memory interface 53 is coupled to the memory management circuit 51 and configured to access the rewritable non-volatile memory module 43. For example, the memory management circuit 51 may access the rewritable non-volatile memory module 43 via the memory interface 53. That is, the data to be written into the rewritable non-volatile memory module 43 is converted into a format acceptable to the rewritable non-volatile memory module 43 via the memory interface 53. Specifically, in a case that the memory management circuit 51 is to access the rewritable non-volatile memory module 43, the memory interface 53 transmits a corresponding command sequence. For example, the command sequence may include a write command sequence instructing data writing, a read command sequence instructing data reading, an erase command sequence instructing data erasing, and corresponding command sequences configured to instruct various memory operations (such as changing read voltage level or performing a garbage collection (CC) operation). The command sequences are generated by, for example, the memory management circuit 51 and sent to the rewritable non-volatile memory module 43 via the memory interface 53. These command sequences may include one or a plurality of signals, or data on a bus. These signals or data may include command codes or program codes. For example, in a read command sequence, information such as a read identification code and a memory address may be included.

In an exemplary embodiment, the memory control circuit unit 42 further includes an error detection and correction (EDAC) circuit 54, a buffer memory 55, and a power management circuit 56.

The EDAC circuit 54 is coupled to the memory management circuit 51 and configured to execute an EDAC operation to ensure the correctness of data. Specifically, when the memory management circuit 51 obtains a write command from the host system 11, the EDAC circuit 54 generates a corresponding error correcting code (ECC) and/or error detecting code (EDC) for the data corresponding to the write command, and the memory management circuit 51 writes the data corresponding to the write command and the corresponding ECC and/or EDC into the rewritable non-volatile memory module 43. Next, when data is read from the rewritable non-volatile memory module 43, the memory management circuit 51 reads the ECC and/or the EDC corresponding to the data at the same time, and the EDAC circuit 54 executes an EDAC operation on the read data based on the ECC and/or the EDC. For example, the EDAC circuit 54 may adopt various encoding/decoding algorithms such as low-density parity check code (LDPC code), BCH code, Reed-Solomon code (RS code), exclusive OR (XOR) code, etc. to encode and decode data.

The buffer memory 55 is coupled to the memory management circuit 51 and configured to temporarily store data. The power management circuit 56 is coupled to the memory management circuit 51 and configured to control the power of the memory storage device 10.

In an exemplary embodiment, the rewritable non-volatile memory module 43 of FIG. 4A may include a flash memory module. In an exemplary embodiment, the memory control circuit unit 42 of FIG. 4A may include a flash memory controller. In an exemplary embodiment, the memory management circuit 51 of FIG. 5 may include a flash memory management circuit.

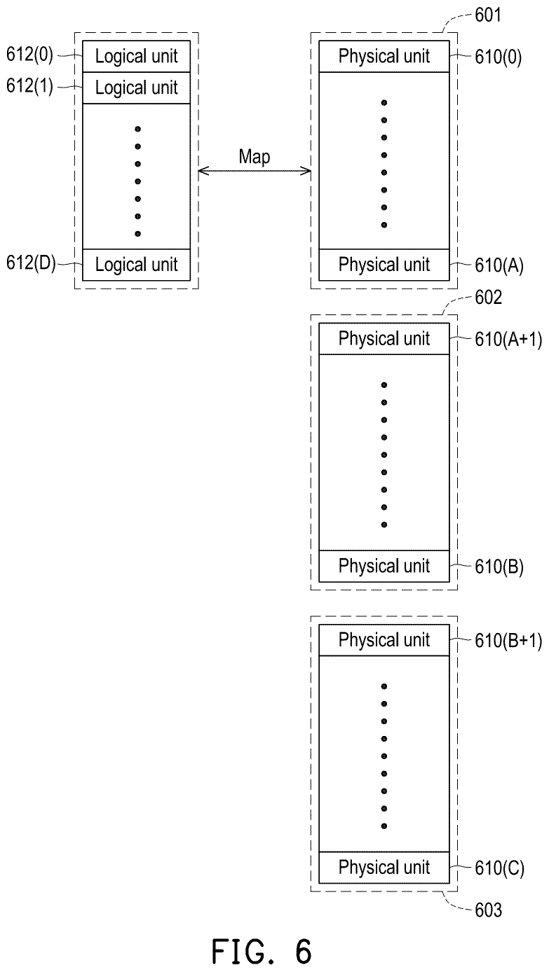

FIG. 6 is a schematic diagram of the management of a rewritable non-volatile memory module shown according to an exemplary embodiment of the invention.

Referring to FIG. 6, the memory management circuit 51 may logically group physical units 610(0) to 610(C) in the rewritable non-volatile memory module 43 into a storage area 601, a spare area 602, and a system area 603.

In an exemplary embodiment, one physical unit refers to one physical address or one physical programming unit. In an exemplary embodiment, one physical unit may also be formed by a plurality of continuous or discontinuous physical addresses.

In an exemplary embodiment, the physical units 610(0) to 610(A) in the storage area 601 are configured to store user data (for example, user data from the host system 11 in FIG. 1). For example, the physical units 610(0) to 610(A) in the storage area 601 may store valid data and invalid data. The physical units 610(A+1) to 610(B) in the spare area 602 do not store data (e.g., valid data). For example, in a case that a certain physical unit does not store valid data, the physical unit may be associated (or added) to the spare area 602. In addition, the physical units in the spare area 602 (or the physical units that do not store valid data) may be erased. When new data is written, one or a plurality of physical units may be extracted from the spare area 602 to store the new data. In an exemplary embodiment, the spare area 602 is also called a free pool.

In an exemplary embodiment, the memory management circuit 51 may configure logical units 612(0) to 612(D) to map the physical units 610(0) to 610(A) in the storage area 601. In an exemplary embodiment, each of the logical units corresponds to one logical address. For example, one logical address may include one or a plurality of logical block addresses (LBAs) or other logical management units. In an exemplary embodiment, one logical unit may also correspond to one logic programming unit or be formed by a plurality of continuous or discontinuous logical addresses.

It should be noted that one logical unit may be mapped to one or a plurality of physical units. In a case that a certain physical unit is currently mapped by a certain logical unit, the data currently stored in the physical unit includes valid data. On the other hand, in a case that a certain physical unit is not currently mapped by any logical unit, the data currently stored in this physical unit is invalid data.

In an exemplary embodiment, the memory management circuit 51 may record management data describing the mapping relationship between logical units and physical units (also called logical-to-physical mapping information) in at least one logical-to-physical mapping table (L2P table). When the host system 11 is to read data from the memory storage device 10 or write data into the memory storage device 10, the memory management circuit 51 may access the rewritable non-volatile memory module 43 according to the information in the logical-to-physical mapping table.

In an exemplary embodiment, the memory management circuit 51 may store specific types of data in the system area 603. For example, the physical units 610(B+1) to 610(C) in the system area 603 may be used exclusively to store data of higher importance and/or data not intended to be accessed or modified by the host system 11. For example, the data of higher importance and/or the data not to be accessed or modified by the host system 11 may include an L2P table, a bad block management table, a wear leveling management table, a valid data management table, and/or other types of management data, which are not limited by the invention. The L2P table is configured to record mapping information. The mapping information may reflect the mapping relationship between logical units and physical units. The bad block management table is configured to record information related to at least one bad block in the rewritable non-volatile memory module 43. The wear leveling management table may be configured to record information related to the wear status of at least one physical unit in the rewritable non-volatile memory module 43 (e.g., a read count, a write count, and/or an erase count). The valid data management table may be configured to record information related to the valid count of at least one physical unit in the rewritable non-volatile memory module 43.

In an exemplary embodiment, the memory management circuit 51 may not map any logical unit to a physical unit in the system area 603. In this way, the data stored in the system area 603 may be prevented from being accessed or modified by the host system 11.

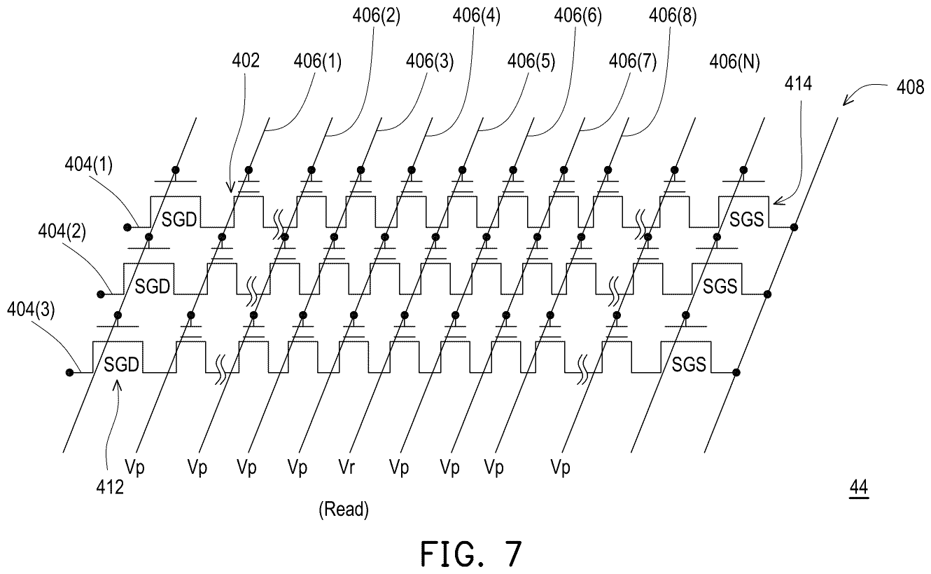

Here, the read pass voltage is described. The read pass voltage is applied to other physical units when reading one physical unit to turn on the memory cells in the other physical units. FIG. 7 is a schematic diagram illustrating read pass voltage according to an embodiment. Please refer to FIG. 7. When the physical unit on the word line 406(5) is to be read, the memory management circuit 51 applies a read voltage Vr to the memory cell connected to the word line 406(5), and simultaneously applies a read pass voltage Vp to the memory cells on the other word lines 406(1) to 406(4) and 406(6) to 406(N). In general, when a read pass voltage is applied, the memory cells should be turned on, and therefore the plurality of bits obtained from the bit lines 404(1) to 404(3) reflect whether the memory cells of the word line 406(5) are turned on. For example, when one memory cell on the word line 406(5) is turned on, bit “1” may be obtained on the corresponding bit line, otherwise bit “0” may be obtained. However, in some applications (such as artificial intelligence), the rewritable non-volatile memory module 43 is frequently read, written, or erased, which may increase the threshold voltage of the memory cell, even higher than the read pass voltage, which may affect the reading of the physical unit. For example, when the threshold voltage of one or a plurality of memory cells on the word line 406(6) exceeds the read pass voltage, these memory cells are cut off, thereby changing the bit obtained on the corresponding bit line. When the threshold voltage of one memory cell exceeds the read pass voltage, the memory cell is called an open bit. In the following embodiments, the read voltage is determined according to the number or the distribution of the open bits.

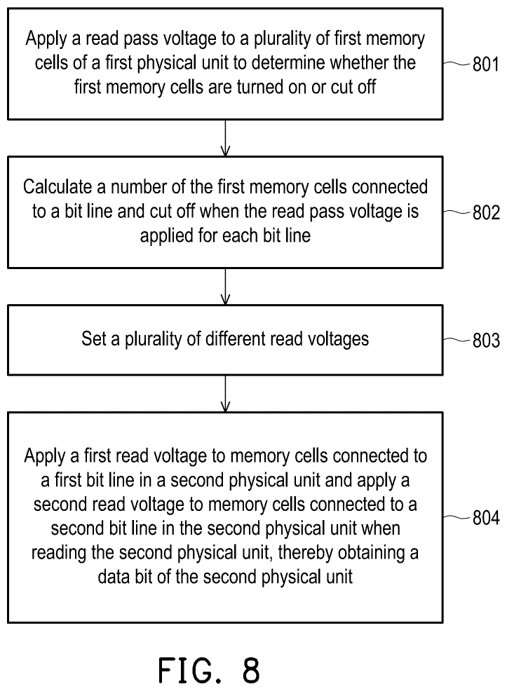

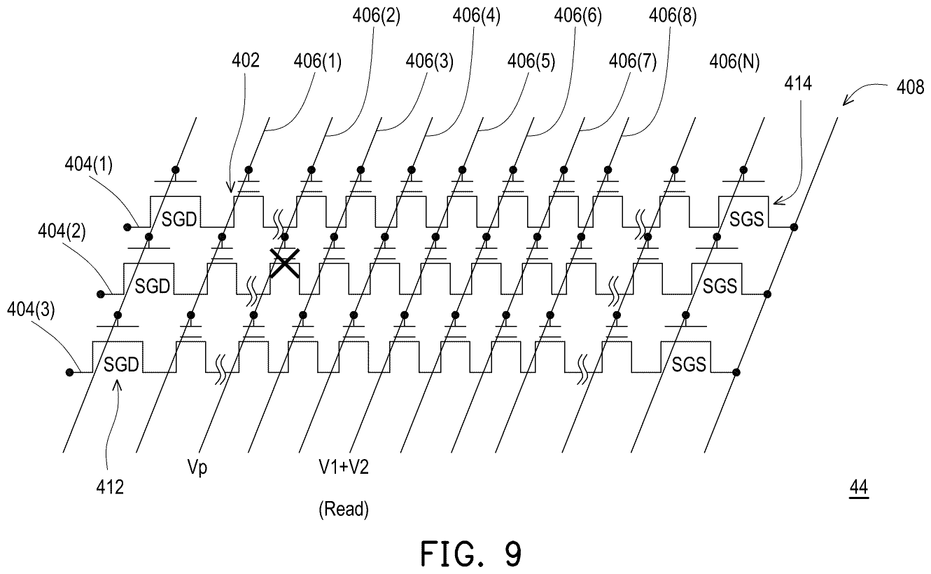

FIG. 8 is a flowchart illustrating a reading method according to an embodiment. The method is executed by the memory management circuit 51 and not described in detail below. Referring to FIG. 8, in step 801, a read pass voltage is applied to a plurality of memory cells (also called first memory cells) of a first physical unit to determine whether the first memory cells are turned on or cut off. Here, the first physical unit is not the physical unit to be read, but as mentioned above, whether there is an open bit in other physical units affects the physical unit to be read. The number of the first physical unit may be one or a plurality, and one first physical unit is taken as an example for description here. FIG. 9 is a schematic diagram illustrating applying a read voltage according to an embodiment. In the embodiment of FIG. 9, the read pass voltage Vp is applied to the first physical unit on the word line 406(2), and the same or higher voltage may be applied to the memory cells on other word lines. When the voltage on the word line 406(2) is lower than the voltage on other word lines, the memory cells on the other word lines have a higher probability of being turned on. In this way, whether each first memory cell on the word line 406(2) is turned on may be determined based on the bits sensed on the bit lines 404(1) to 404(3). When the voltage of the word line 406(2) is the same as the voltage on the other word lines, whether a memory cell on the corresponding bit line is cut off may be determined according to the bits sensed on the bit lines 404(1) to 404(3). Such information also reflects the degree of degradation of the physical block and may therefore be used to determine the read voltage.

In step 802, for each bit line, the number of first memory cells connected to the bit line and cut off when a read pass voltage is applied (called the open bit number) is calculated. It is assumed here that the first memory cell connected to the bit line 404(1) and the word line 406(2) is turned on when the read pass voltage Vp is applied; the first memory cell connected to the bit line 404(2) and the word line 406(2) is cut off when the read pass voltage Vp is applied; and the first memory cell connected to the bit line 404(3) and the word line 406(2) is turned on when the read pass voltage Vp is applied. Therefore, the open bit number corresponding to the bit line 404(1) is 0, the open bit number corresponding to the bit line 404(2) is 1, and the open bit number corresponding to the bit line 404(3) is 0. In other words, the open bit number corresponding to the bit lines 404(1) and 404(3) is different from the open bit number corresponding to the bit line 404(2).

In step 803, a plurality of different read voltages are set. One of the read voltages may be the same as the preset read voltage, and another one may be greater than the preset read voltage. Here, the two read voltages are respectively called a first read voltage and a second read voltage.

In step 804, when reading the second physical unit (for example, the physical unit on the word line 406(5)), a first read voltage V1 is applied to the memory cell connected to bit line 404(2) in the second physical unit, and a second read voltage V2 is applied to the memory cells connected to bit lines 404(1) and 404(3) in the second physical unit, thereby obtaining a plurality of data bits of the second physical unit. Here, the first read voltage V1 and the second read voltage V2 are applied to the word line 406(5) at different time points. For example, first, the first read voltage V1 is applied to the word line 406(5), a read pass voltage is applied to the other word lines, and one bit is obtained from the bit line 404(2); then, the second read voltage V2 is applied to the word line 406(5), a read pass voltage is applied to the other word lines, and two bits are obtained from the bit lines 404(1) and 404(3). The three bits obtained above are the plurality of data bits in the second physical unit.

In some embodiments, the open bit number and the read voltages are positively correlated. For example, the open bit number corresponding to the bit line 404(2) is greater than the open bit numbers corresponding to the bit lines 404(1) and 404(3). Therefore, the first read voltage V1 may be set to be greater than the second read voltage V2.

As described above, the second physical unit on the word line 406(5) is different from the first physical unit on the word line 406(2). In other words, when one physical unit is to be read, the read voltage is determined according to the open bits on the other physical units. In some embodiments, the position of the first physical unit may be determined in advance. After the rewritable non-volatile memory module 43 is produced, which word lines are prone to memory cell defects may be determined via any detection means, and therefore the physical units on these word lines are set to the first physical unit. In some embodiments, different first physical units may be disposed on different physical blocks or different dies to reflect different physical properties.

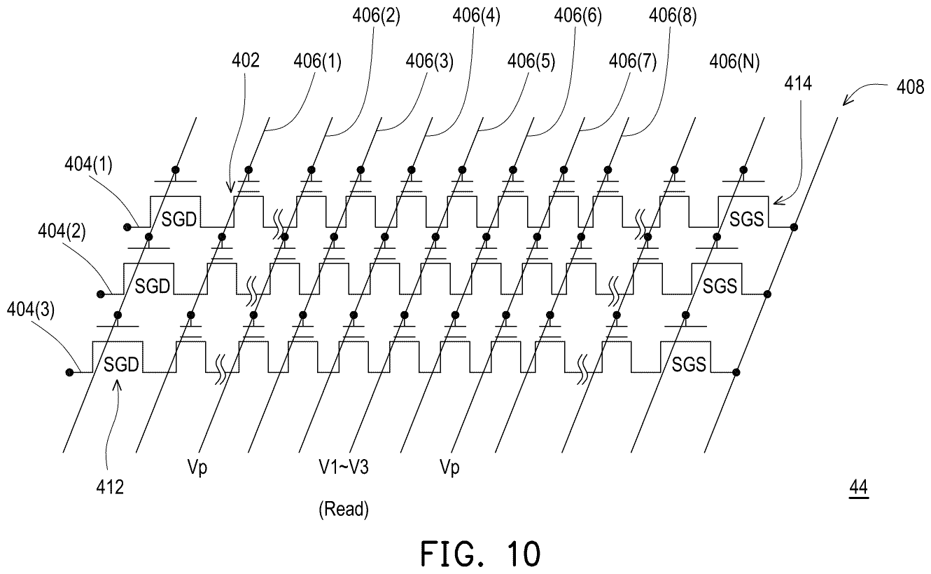

The number of the first physical unit is 1, but in other embodiments, the number of the first physical unit may be greater than 1. For example, in FIG. 10, the read pass voltage Vp is first applied to the memory cells of the first physical units on the word lines 406(2) and 406(7) to determine whether these memory cells are turned on or cut off. Then, for each bit line, the number of memory cells connected to the bit line and cut off when the read pass voltage Vp is applied (called the open bit number) is calculated. Possible values of the open bit number include 0, 1, and 2. Different open bit numbers correspond to different read voltages. In some embodiments, the read voltage may be set according to the open bit number, such that the open bit number and the read voltages are positively correlated. For example, when the open bit number is equal to 2, a first read voltage is used; when the open bit number is equal to 1, a second read voltage is used; when the open bit number is equal to 0, a third read voltage is used, wherein the first read voltage is greater than the second read voltage, and the second read voltage is greater than the third read voltage.

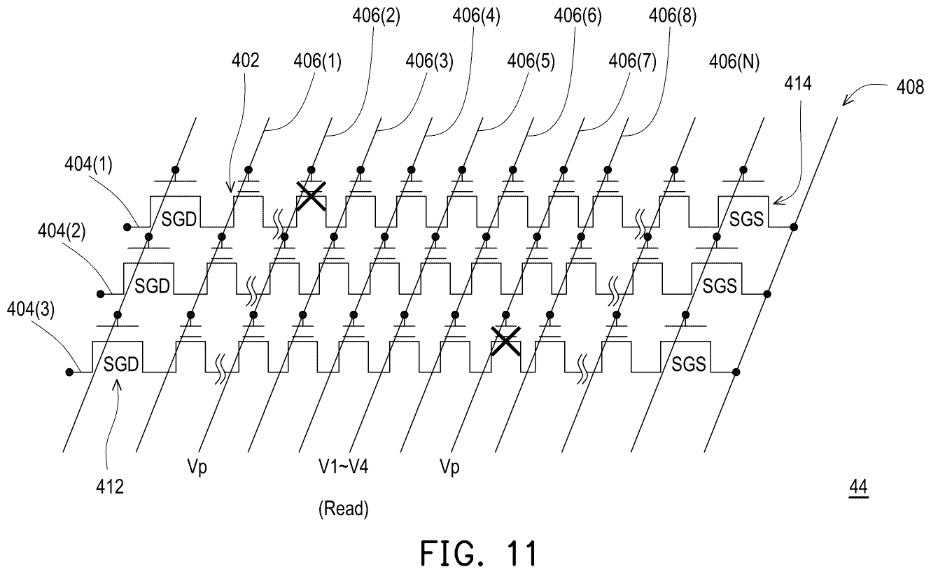

In some embodiments, in a case that the open bit numbers of two bit lines are the same but the positions of the open bits are different, different read voltages may be used. For example, referring to FIG. 11, when a read pass voltage is applied to the word lines 406(2) and 406(7), the memory cell connected to the word line 406(2) and the bit line 404(1) is cut off, the memory cell connected to the word line 406(2) and the bit line 404(2) is turned on, the memory cell connected to the word line 406(2) and the bit line 404(3) is turned on, the memory cell connected to the word line 406(7) and the bit line 404(1) is turned on, the memory cell connected to the word line 406(7) and the bit line 404(2) is turned on, and the memory cell connected to the word line 406(7) and the bit line 404(3) is cut off. In such an example, the open bit numbers of the bit line 404(1) and the bit line 404(3) are both 1, but the open bit on the bit line 404(1) occurs on the word line 406(2), and the open bit on the bit line 404(3) occurs on the word line 406(7). A plurality of groups may be generated according to the distribution of the open bits on a bit line, and each bit line belongs to one of the groups. The distribution may be represented by a plurality of bits, and each bit represents whether there is an open bit on a corresponding word line. When a read pass voltage is applied to one word line, there are two groups (cut off or turned on). When a read pass voltage is applied to two word lines, four groups may be generated. When a read pass voltage is applied to three word lines, eight groups may be generated. When a read pass voltage is applied to four word lines, sixteen groups may be generated, and so on. For example, in the embodiment of FIG. 11, four groups may be represented as shown in Table 1 below.

TABLE 1

| | Word line 406(2) | Word line 406(7) |
|---|---|---|
| First group | 1 | 1 |
| Second group | 1 | 0 |
| Third group | 0 | 1 |
| Fourth group | 0 | 0 |

In Table 1, “1” indicates that the corresponding memory cell is an open bit, and “0” indicates a non-open bit. Specifically, the bit line 404(1) belongs to the second group, the bit line 404(2) belongs to the fourth group, and the bit line 404(3) belongs to the third group. The first to fourth groups correspond to the first read voltage V1 to the fourth read voltage V4 respectively. Therefore, when reading the physical unit on the word line 406(5), the second read voltage V2, the fourth read voltage V4, and the third read voltage V3 may be applied to the word line 406(5) at different time points to read the data bits from the memory cells connected to the bit lines 404(1) to 404(3) respectively. It is worth noting that FIG. 11 shows the first to fourth read voltages V1 to V4 being applied to the word line 406(5) since in practice the number of bit lines is significantly greater than 3, and therefore some bit lines also belong to the first group (using the first read voltage V1).

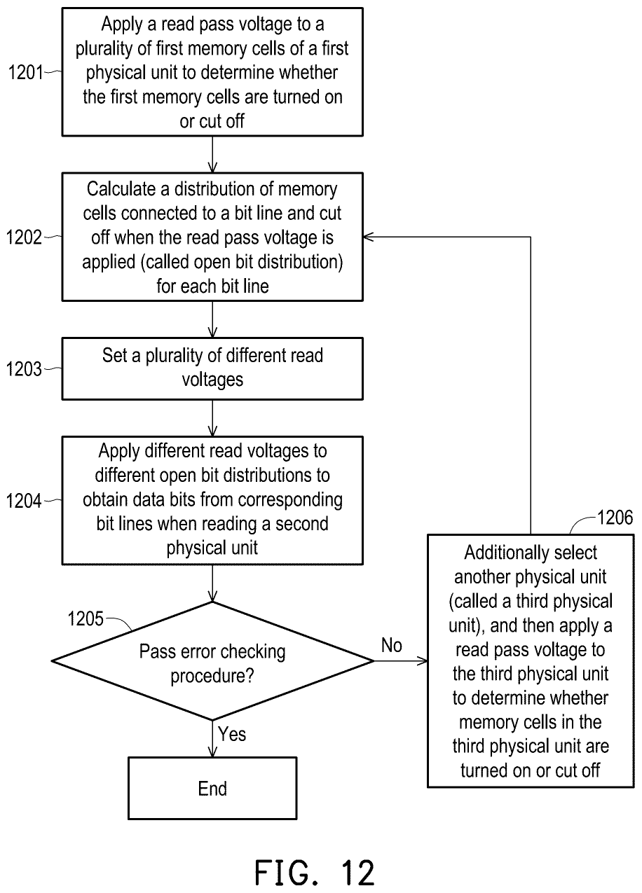

FIG. 12 is a flowchart illustrating a reading method according to another embodiment. In the embodiment of FIG. 12, the number of word lines to which the read pass voltage is applied is gradually increased. In step 1201, a read pass voltage is applied to a plurality of first memory cells of a first physical unit to determine whether the first memory cells are turned on or cut off. This step 1201 is the same as step 801.

In step 1202, for each bit line, the distribution of memory cells connected to the bit line and cut off when a read pass voltage is applied (called open bit distribution) is calculated. Here, the open bit distribution may include position information of each open bit (see Table 1). When the number of the first physical unit is M, there are 2^{A}M different open bit distributions, wherein M is a positive integer.

In step 1203, a plurality of different read voltages are set. For example, a different read voltage may be set for each open bit distribution.

In step 1204, when reading the second physical unit, different read voltages are applied to different open bit distributions to obtain data bits from corresponding bit lines. For example, in the embodiment of FIG. 11, the open bit distributions of the bit lines 404(1) to 404(3) are all different from each other, and therefore three different read voltages are applied to the word line 406(5).

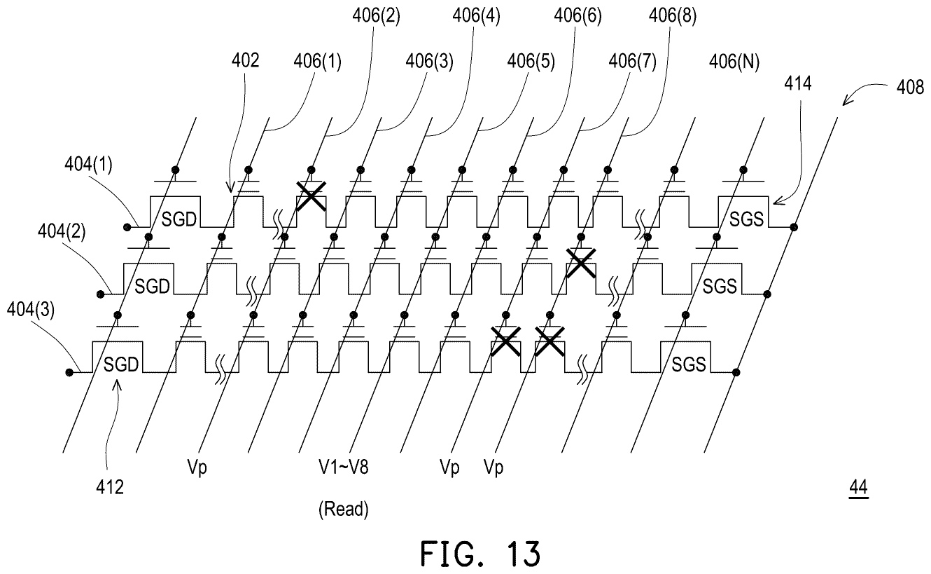

In step 1205, whether the obtained data bits (also called first data bits) pass one error checking procedure is determined, for example, whether the first data bits may be completely corrected according to an error correcting code is determined. In a case of not passing the error checking procedure, in step 1206, another physical unit (called a third physical unit) is additionally selected, and then a read pass voltage is applied to the third physical unit to determine whether the memory cells in the third physical unit are turned on or cut off. FIG. 13 is a schematic diagram illustrating selecting a third physical unit according to an embodiment. FIG. 13 is a continuation of the embodiment of FIG. 11, assuming that the word line 406(8) is additionally selected. After applying the read pass voltage Vp to the third physical unit on the word line 406(8), the memory cells connected to the bit line 404(1) are turned on, the memory cells connected to the bit line 404(2) are cut off, and the memory cells connected to the bit line 404(3) are cut off.

Next, step 1202 is repeated to recalculate the open bit distribution. At this time, not only the memory cells of the word lines 406(2) and 406(7) are calculated, but also the memory cells of the word line 406(8). Since there are currently three word lines being applied with the read pass voltage Vp, there are a total of 8 open bit distributions (i.e., 8 groups), which may be represented as shown in Table 2 below.

TABLE 2

| | Word line 406(2) | Word line 406(7) | Word line 406(8) |
|---|---|---|---|
| First group | 1 | 1 | 1 |
| Second group | 1 | 1 | 0 |
| Third group | 1 | 0 | 1 |
| Fourth group | 1 | 0 | 0 |
| Fifth group | 0 | 1 | 1 |
| Sixth group | 0 | 1 | 0 |
| Seventh group | 0 | 0 | 1 |
| Eighth group | 0 | 0 | 0 |

Similarly, in Table 2, “1” indicates that the corresponding memory cell is an open bit, and “0” indicates a non-open bit. In the example of FIG. 13, the bit line 404(1) belongs to the fourth group, the bit line 404(2) belongs to the seventh group, and the bit line 404(3) belongs to the fifth group. In other words, the open bit distributions of the bit lines 404(1) to 404(3) are different from each other.

In step 1203, a plurality of read voltages are set. After a word line is added, eight different read voltages may be set, corresponding to the eight groups respectively. These eight read voltages may be determined via experiments. It is assumed that the first to eighth groups correspond to the first to eighth read voltages respectively. In some embodiments, when the number of open bits in one group is greater, the corresponding read voltage is also greater. For example, there are three open bits in the first group, two open bits in the second group, and one open bit in the fourth group, and therefore the first read voltage is greater than the second read voltage, and the second read voltage is greater than the fourth read voltage.

In step 1204, when the second physical unit on the word line 406(5) is read again, different read voltages are applied to different open bit distributions to obtain data bits from the corresponding bit lines. In this example, the fourth read voltage may be applied to the word line 406(5) first to obtain one data bit from the bit line 404(1), then a fifth read voltage may be applied to the word line 406(5) to obtain one data bit from the bit line 404(3), and then a seventh read voltage may be applied to the word line 406(5) to obtain one data bit from the bit line 404(2).

The resulting three data bits are determined again in step 1205. In a case of not passing the error checking procedure, another physical unit is selected in step 1206. The above approach may gradually increase the decoding capacity and avoid reading too many times at the beginning and spending too much time or computing resources.

Please refer to FIG. 5. In some embodiments, the memory management circuit 51 may apply a read pass voltage to a plurality of physical units in advance (for example, when idle). After the open bit number or the open bit distribution corresponding to each bit line is calculated, these open bit numbers or open bit distributions may be stored in the buffer memory 55. When one physical unit is to be read, the memory management circuit 51 may read the open bit number or the open bit distribution from the buffer memory 55 to determine which read voltage to apply to the memory cells on which bit line. As a result, the reading speed may be increased.

In the above embodiment, when reading the second physical unit, the read voltage is determined according to the open bits on the first physical unit. In other embodiments, the initial read voltage of the second physical unit may also be determined according to the number of open bits on the second physical unit. In general, when the number of open bits on the second physical unit is greater, the initial read voltage is also greater. Here, the number of open bits may be converted into the read voltage via one function or one lookup table.

In some embodiments, the processes of FIG. 8 and FIG. 12 are performed only after a normal reading procedure fails. For example, the reading procedure may include a hard bit decoding procedure and a soft bit decoding procedure. In the hard bit decoding procedure, one read voltage (i.e., an initial read voltage) is set, and data bits may be obtained according to whether the corresponding memory cell is turned on under the read voltage. Next, the data bits are subjected to an error correcting code decoding procedure to correct the error bits therein. In a case that the number of error bits is too large and exceeds the correction capability of the error correcting code, the hard bit decoding procedure fails. When the hard bit decoding procedure fails, a soft bit decoding procedure is performed. In the soft bit decoding procedure, a plurality of read voltages are set, and a probability value may be calculated according to whether the corresponding memory cell is turned on under these read voltages. Then, the probability values are subjected to an error correcting code (e.g., LDPC) decoding procedure to obtain the final data bits. In a case that the data bits may not be completely corrected, the soft bit decoding procedure fails. When the soft bit decoding procedure fails, the process of FIG. 8 or FIG. 12 is performed. In an embodiment, there are still 214 error bits in the soft bit decoding procedure, but after 16 groups are set to adjust the read voltage, the number of error bits is reduced to 131. That is, the above method may reduce the number of error bits.

Although the invention has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. A reading method, for a rewritable non-volatile memory module, wherein the rewritable non-volatile memory module comprises a plurality of physical units and a plurality of bit lines, and the reading method comprises:
applying a read pass voltage to a plurality of first memory cells of at least one first physical unit in the physical units to determine whether the first memory cells are turned on or cut off, wherein each of the first memory cells is connected to one of the bit lines;
calculating an open bit number of the first memory cells connected to the bit line and cut off when the read pass voltage is applied for each of the bit lines, wherein the bit lines comprise a first bit line and a second bit line, and the open bit number corresponding to the first bit line is different from the open bit number corresponding to the second bit line;
setting a plurality of read voltages, wherein the read voltages comprise a first read voltage and a second read voltage, and the first read voltage is different from the second read voltage;
applying the first read voltage to a second memory cell connected to the first bit line in a second physical unit and applying the second read voltage to a second memory cell connected to the second bit line in the second physical unit when reading the second physical unit in the physical units, thereby obtaining a plurality of first data bits of the second physical unit.

2. The reading method of claim 1, wherein the open bit number corresponding to the first bit line is greater than the open bit number corresponding to the second bit line, and the first read voltage is greater than the second read voltage.

3. The reading method of claim 1, wherein the step of setting the read voltages comprises:
setting the read voltages according to the open bit numbers corresponding to the bit lines, wherein the open bit numbers and the read voltages are positively correlated.

4. The reading method of claim 1, further comprising:
determining whether the first data bits pass an error checking procedure;
applying the read pass voltage to a plurality of third memory cells of a third physical unit in the physical units to determine whether the third memory cells are turned on or cut off in a case that the first data bits do not pass the error checking procedure, wherein each of the third memory cells is connected to one of the bit lines;
calculating an open bit distribution of the first memory cells and the third memory cells connected to the bit line and cut off when the read pass voltage is applied for each of the bit lines, wherein the open bit distribution corresponding to the first bit line is different from the open bit distribution corresponding to the second bit line; and
applying a third read voltage in the read voltages to the second memory cell connected to the first bit line in the second physical unit, and applying a fourth read voltage in the read voltages to the second memory cell connected to the second bit line in the second physical unit, thereby reading a plurality of second data bits of the second physical unit.

5. The reading method of claim 4, wherein a number of the first memory cells and the third memory cells connected to the first bit line and cut off when the read pass voltage is applied is greater than a number of the first memory cells and the third memory cells connected to the second bit line and cut off when the read pass voltage is applied, and the third read voltage is greater than the fourth read voltage.

6. The reading method of claim 4, further comprising:
storing the open bit distributions corresponding to the bit lines in a buffer memory; and
reading the open bit distributions from the buffer memory to determine that the first bit line corresponds to the first read voltage and the second bit line corresponds to the second read voltage when reading the second physical unit.

7. The reading method of claim 1, wherein the second physical unit is different from the at least one first physical unit.

8. A memory storage device, comprising:
a connection interface unit configured to be coupled to a host system;
a rewritable non-volatile memory module, wherein the rewritable non-volatile memory module comprises a plurality of physical units and a plurality of bit lines; and
a memory control circuit unit coupled to the connection interface unit and the rewritable non-volatile memory module, and configured to perform a plurality of steps:
applying a read pass voltage to a plurality of first memory cells of at least one first physical unit in the physical units to determine whether the first memory cells are turned on or cut off, wherein each of the first memory cells is connected to one of the bit lines;
calculating an open bit number of the first memory cells connected to the bit line and cut off when the read pass voltage is applied for each of the bit lines, wherein the bit lines comprise a first bit line and a second bit line, and the open bit number corresponding to the first bit line is different from the open bit number corresponding to the second bit line;
setting a plurality of read voltages, wherein the read voltages comprise a first read voltage and a second read voltage, and the first read voltage is different from the second read voltage;
applying the first read voltage to a second memory cell connected to the first bit line in a second physical unit and applying the second read voltage to a second memory cell connected to the second bit line in the second physical unit when reading the second physical unit in the physical units, thereby obtaining a plurality of first data bits of the second physical unit.

9. The memory storage device of claim 8, wherein the open bit number corresponding to the first bit line is greater than the open bit number corresponding to the second bit line, and the first read voltage is greater than the second read voltage.

10. The memory storage device of claim 8, wherein the step of setting the read voltages comprises:
setting the read voltages according to the open bit numbers corresponding to the bit lines, wherein the open bit numbers and the read voltages are positively correlated.

11. The memory storage device of claim 8, wherein the steps further comprise:
determining whether the first data bits pass an error checking procedure;
applying the read pass voltage to a plurality of third memory cells of a third physical unit in the physical units to determine whether the third memory cells are turned on or cut off in a case that the first data bits do not pass the error checking procedure, wherein each of the third memory cells is connected to one of the bit lines;
calculating an open bit distribution of the first memory cells and the third memory cells connected to the bit line and cut off when the read pass voltage is applied for each of the bit lines, wherein the open bit distribution corresponding to the first bit line is different from the open bit distribution corresponding to the second bit line; and
applying a third read voltage in the read voltages to the second memory cell connected to the first bit line in the second physical unit, and applying a fourth read voltage in the read voltages to the second memory cell connected to the second bit line in the second physical unit, thereby reading a plurality of second data bits of the second physical unit.

12. The memory storage device of claim 11, wherein a number of the first memory cells and the third memory cells connected to the first bit line and cut off when the read pass voltage is applied is greater than a number of the first memory cells and the third memory cells connected to the second bit line and cut off when the read pass voltage is applied, and the third read voltage is greater than the fourth read voltage.

13. The memory storage device of claim 11, wherein the steps further comprise:
storing the open bit distributions corresponding to the bit lines in a buffer memory; and
reading the open bit distributions from the buffer memory to determine that the first bit line corresponds to the first read voltage and the second bit line corresponds to the second read voltage when reading the second physical unit.

14. The memory storage device of claim 8, wherein the second physical unit is different from the at least one first physical unit.

15. A memory control circuit unit, configured to control a rewritable non-volatile memory module, wherein the rewritable non-volatile memory module comprises a plurality of physical units and a plurality of bit lines, and the memory control circuit unit comprises:
a host interface configured to be coupled to a host system;
a memory interface configured to be coupled to the rewritable non-volatile memory module;
a memory management circuit coupled to the host interface and the memory interface, and configured to perform a plurality of steps:
applying a read pass voltage to a plurality of first memory cells of at least one first physical unit in the physical units to determine whether the first memory cells are turned on or cut off, wherein each of the first memory cells is connected to one of the bit lines;
calculating an open bit number of the first memory cells connected to the bit line and cut off when the read pass voltage is applied for each of the bit lines, wherein the bit lines comprise a first bit line and a second bit line, and the open bit number corresponding to the first bit line is different from the open bit number corresponding to the second bit line;
setting a plurality of read voltages, wherein the read voltages comprise a first read voltage and a second read voltage, and the first read voltage is different from the second read voltage;
applying the first read voltage to a second memory cell connected to the first bit line in a second physical unit and applying the second read voltage to a second memory cell connected to the second bit line in the second physical unit when reading the second physical unit in the physical units, thereby obtaining a plurality of first data bits of the second physical unit.

16. The memory control circuit unit of claim 15, wherein the open bit number corresponding to the first bit line is greater than the open bit number corresponding to the second bit line, and the first read voltage is greater than the second read voltage.

17. The memory control circuit unit of claim 15, wherein the step of setting the read voltages comprises:
setting the read voltages according to the open bit numbers corresponding to the bit lines, wherein the open bit numbers and the read voltages are positively correlated.

18. The memory control circuit unit of claim 15, wherein the steps further comprise:
determining whether the first data bits pass an error checking procedure;
applying the read pass voltage to a plurality of third memory cells of a third physical unit in the physical units to determine whether the third memory cells are turned on or cut off in a case that the first data bits do not pass the error checking procedure, wherein each of the third memory cells is connected to one of the bit lines;
calculating an open bit distribution of the first memory cells and the third memory cells connected to the bit line and cut off when the read pass voltage is applied for each of the bit lines, wherein the open bit distribution corresponding to the first bit line is different from the open bit distribution corresponding to the second bit line; and
applying a third read voltage in the read voltages to the second memory cell connected to the first bit line in the second physical unit, and applying a fourth read voltage in the read voltages to the second memory cell connected to the second bit line in the second physical unit, thereby reading a plurality of second data bits of the second physical unit.

19. The memory control circuit unit of claim 18, wherein a number of the first memory cells and the third memory cells connected to the first bit line and cut off when the read pass voltage is applied is greater than a number of the first memory cells and the third memory cells connected to the second bit line and cut off when the read pass voltage is applied, and the third read voltage is greater than the fourth read voltage.

20. The memory control circuit unit of claim 18, wherein the steps further comprise:
storing the open bit distributions corresponding to the bit lines in a buffer memory; and
reading the open bit distributions from the buffer memory to determine that the first bit line corresponds to the first read voltage and the second bit line corresponds to the second read voltage when reading the second physical unit.

21. The memory control circuit unit of claim 15, wherein the second physical unit is different from the at least one first physical unit.
